(19) United States
(12) Patent Application Publication
(10) Pub. No.: US 2011/0297228 A1
(43) Pub. Date: Dec. 8, 2011

(54) UV BLOCKING FLUOROPOLYMER FILM

(76) Inventors: Rongfu Li, Shrewsbury, MA (US); Ran Ding, Bolton, MA (US); Oh-hun Kwon, Westborough, MA (US)

(21) Appl. No.: 12/960,984

(22) Filed: Dec. 6, 2010

Related U.S. Application Data
(60) Provisional application No. 61/267,274, filed on Dec. 7, 2009.

(51) Int. Cl. C08F 259/08; H01L 31/0203

(52) U.S. Cl. 136/259; 525/276

(57) ABSTRACT

The invention describes a polymer that is composed of a fluoropolymer modified with a UV absorber. The UV absorber is grafted to the polymeric backbone of the fluoropolymer. Optionally, a HALS can also be grated to the polymeric backbone of the fluoropolymer. Incorporation or the absorber or stabilizer helps to reduce degradation of underlying layers such as an encapsulant while still allowing useful light energy to pass through the layers to a device, such as a photovoltaic device.

### CROSS REFERENCE TO RELATED APPLICATIONS

This application claims benefit under 35 U.S.C. §119(e) to U.S. Provisional Patent Application No. 61/267,274, filed Dec. 7, 2009, entitled “UV BLOCKING FLUOROPOLYMER FILM” (attorney docket number SGPP-037/PROV), the contents of which is incorporated herein in their entirety for all purposes.

### FIELD OF THE INVENTION

The invention relates generally to use of materials that absorb ultraviolet light in fluoropolymeric materials.

### BACKGROUND OF THE INVENTION

Multilayer films or laminates are constructions which attempt to incorporate the properties of dissimilar materials in order to provide an improved performance versus the materials separately. Such properties include barrier resistance to elements such as water, cut-through resistance, weathering resistance and/or electrical insulation. Up until the present invention, such laminates often result in a mis-balance of properties, are expensive, or difficult to handle or process. In particular applications, such as in a photovoltaic back sheet, good interlayer adhesion is needed. In addition, the inner layers may not be fully durable over the life of the laminate without additional protection.

Typical photovoltaic devices include, for example, a “top sheet” which is transparent to light, an “encapsulant” which helps cushion and protect the photovoltaic component, and a back sheet as noted above. The encapsulant is generally a thermoplastic material that requires the inclusion of ultraviolet (UV) light absorbers to protect the material from degradation. Without the inclusion of UV absorbers in the encapsulant, the encapsulant degrades, becomes brittle, and does not effectively protect the photovoltaic component. Therefore, the operating time of the photovoltaic device is greatly diminished and thus becomes a costly issue to the user.

Therefore, a need exists for modification of multilayer films or laminates that overcomes one or more of the current disadvantages noted above.

### BRIEF SUMMARY OF THE INVENTION

The present invention surprisingly provides compositions, films or multilayer films that include a suitable fluoropolymer that is modified with a functionalized ultraviolet light (UV) absorber. Typical functionalized UV absorbers contain a reactive acrylate or methacrylate moiety such that under appropriate conditions the fluoropolymer and functionalized UV absorber can react to provide the modified fluoropolymer.

Alternatively, a functionalized fluoropolymer can be reacted with a suitable UV absorber. For example, an anhydride or carboxylic acid containing fluoropolymer can be reacted with a UV absorber that includes at least one hydroxyl group.

The UV absorber is present in an amount such that the light transmittance of the fluoropolymer in the visible light range is not substantially decreased. By this we mean that the light transmitted through the fluoropolymer in the visible range (from about 380 to 750 nm) when containing UV absorber is greater than about 80% of the film without the UV absorber, or even about 90% or 95% or greater, e.g., 96-99%, particularly 100% of the transmittance of the film without the UV absorber. Suitable levels of UV absorber present in the fluoropolymer film range from about 0.1 to about 10 weight percent, based on the total weight of the fluoropolymer film, for example, 5 weight percent.

Additionally, a hindered amine light stabilizer (HALS) can also be added to the film. Again, the HALS is present in an amount such that the light transmittance of the fluoropolymer in the visible light range is not substantially decreased. By this we mean that the light transmitted through the fluoropolymer in the visible range (from about 380 to 750 nm) when containing the HALS is greater than about 85% of the film without the HALS, or even about 90% or 95%, e.g., 96-99%, particularly 100% of the transmittance of the film without the HALS. Suitable levels of HALS present in the fluoropolymer film range from about 0.1 to about 5 weight percent, based on the total weight of the fluoropolymer film.

The present invention thus provides the advantage that the film layers under the fluoropolymer such as an encapsulant are protected while not requiring a UV absorber within the film layers about the encapsulant. This can be an advantage in that for certain encapsulant compositions, such as EVA (ethylene vinyl acetate copolymer) with peroxide cure, balancing interaction between different additives can be difficult. It is even possible that a percentage of the UV absorber could be rendered inactive during the curing process. As a further advantage, having the UV protection in the fluoropolymer can also protect other underlying packaging films that are degraded by UV. Laminates with polyester films are one such class of films damaged by UV.

While multiple embodiments are disclosed, still other embodiments of the present invention will become apparent to those skilled in the art from the following detailed description. As will be apparent, the invention is capable of modifications in various obvious aspects, all without departing from the spirit and scope of the present invention. Accordingly, the detailed descriptions are to be regarded as illustrative in nature and not restrictive.

### BRIEF DESCRIPTION OF THE DRAWINGS

FIG. 1 provides a multilayer film of the invention that includes 5 layers. The multilayer film includes an outer UV blocking fluoropolymer film of the invention, encapsulant layers for a photovoltaic cell, a photovoltaic device and a backsheet material.

FIG. 2 provides a multilayer film of the invention that includes 7 layers. The multilayer film includes a UV blocking fluoropolymer film of the invention, a tie or adhesive layer, a transparent barrier layer, e.g., PET, encapsulant layers for a photovoltaic cell, a photovoltaic device and a backsheet material.

### DETAILED DESCRIPTION

In the specification and in the claims, the terms “including” and “comprising” are open-ended terms and should be interpreted to mean “including, but not limited to . . . ” These terms encompass the more restrictive terms “consisting essentially of” and “consisting of.”

It must be noted that as used herein and in the appended claims, the singular forms “a”, “an”, and “the” include plural reference unless the context clearly dictates otherwise. As well, the terms “a” (or “an”), “one or more” and “at least one” can be used interchangeably herein. It is also to be noted that the terms “comprising”, “including”, “characterized by” and “having” can be used interchangeably.

Unless defined otherwise, all technical and scientific terms used herein have the same meanings as commonly understood by one of ordinary skill in the art to which this invention belongs. All publications and patents specifically mentioned herein are incorporated by reference in their entirety for all purposes including describing and disclosing the chemicals, instruments, statistical analyses and methodologies which are reported in the publications which might be used in connection with the invention. All references cited in this specification are to be taken as indicative of the level of skill in the art. Nothing herein is to be construed as an admission that the invention is not entitled to antedate such disclosure by virtue of prior invention.

The present invention provides a unique solution to the issue where encapsulants or other polymer films tend to degrade upon exposure to UV radiation. The films, polymers and compositions of the invention include UV absorbers and/or hindered amine light stabilizers to either absorb UV radiation or inhibit degradation of the polymer or both. The additives are found in a fluoropolymer film or composition and not in the encapsulant or other polymer film.

The present invention also provide methods to prepare the compositions, films and polymers described herein.

The compositions, films and polymers described herein can be used in photovoltaic devices where the device can receive light from a front side, a back side or both. Backsheet materials can be protected by the compositions, films and polymers described herein as well as any polymer films susceptible to UV degradation. For example, architectural membrane materials can be protected from UV degradation by the compositions, films and polymers described herein.

In an embodiment, the films and compositions of this invention can be used to provide both UV protection and light transmission to underlying transparent layers which themselves further transmit light. In another embodiment, the invention can also be effective in protecting underlying opaque layers not designed to further transmit light, where it is still desirable to have the protection provided within the fluoropolymer composition or film.

In one aspect a fluoropolymer combined with a functionalized UV absorber and subjected to conditions to cause reactive sites on the fluoropolymer to combine with the reactive portion of the UV absorber. This can be accomplished by use of radical initiators or high energy radiation such as X-ray, e-beam or gamma rays. A suitable labile atom, such as a hydrogen or halogen is removed from the fluoropolymer backbone generating a reactive site which then in turn reacts with the functionalized UV absorber through an acrylate, methacrylate, vinyl or allyl group. Similarly, a functionalized HALS can undergo such reactions.

In another aspect, the fluoropolymer can be functionalized by having a carboxylic acid or anhydride group in the polymeric backbone. This functionality can then react under suitable conditions with a UV absorber that includes, for example, either a hydroxyl group, a leaving group or a nucleophilic group. Similarly, HALS with an appropriate group can also undergo such a reaction.

The fluoropolymer and functionalized UV absorber (and HALS) can be reacted in a batch process, under reaction extrusion conditions or reactive compounding conditions. Such conditions can be produced using a twin screw extruder, brabender compounder or the like to render the fluoropolymer into its molten state. The functionalized UV absorber is added to the molten fluoropolymer. Under conditions of heat and shear the functionalized UV absorber will react with the fluoropolymer, grafting to the polymer chain. In one embodiment, an initiator may further be added to accelerate the grafting reaction. Similarly, a functionalized fluoropolymer can be reacted with a suitable UV absorber (and HALS) in a batch process, under reaction extrusion conditions or reactive compounding process using the same processes as described above.

A multilayer film can be prepared with the films, polymers or compositions of the invention along with an encapsulant. The encapsulant does not require the inclusion of a UV absorber or HALS since these materials are included in the protective fluoropolymer.

Multilayer films of the invention can be prepared by coextrusion, coprocessing and/or colamination. In one embodiment, the multilayer film includes a fluoropolymer/UV absorber film and an encapsulant film. In another embodiment, the multilayer film can be adhered to a photovoltaic device.

It should be understood that the laminates of the invention can include from 2 layers to about 12 layers of material. For example, the laminates can repeat layering of a first layer and a second layer, and so forth. Additionally, combinations of various layers are included herein, for example, a first layer, a second layer, a third layer differing from the first or second layers and a fourth layer which differs from the first, second or third layers, etc. This layering, again, can be repeated as needed for the application envisioned.

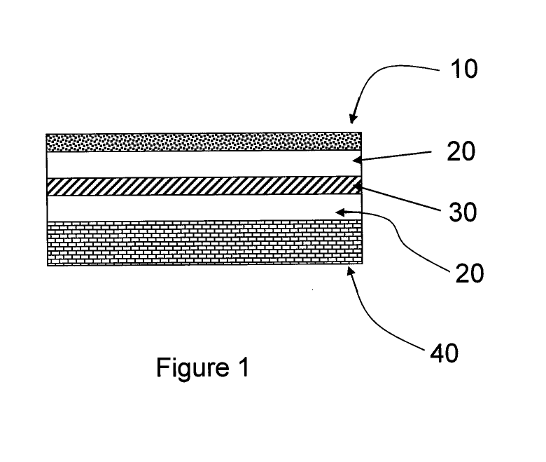

For example, as provided in FIG. 1, in one embodiment, the multilayer film can include 5 layers. Layer 10 is a UV blocking fluoropolymer film as described and prepared herein. Layers 20 are transparent encapsulant layers to protect the photovoltaic device 30. Layer 40 is a suitable backsheet for the photovoltaic device.

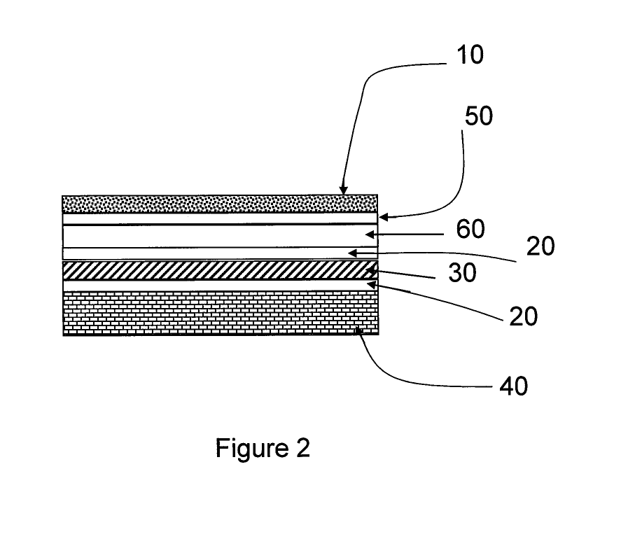

In another embodiment, as provided in FIG. 2, the multilayer film can include 7 layers. Layer 10 is a UV blocking fluoropolymer film as described and prepared herein. Layer 50 is a transparent tie or adhesive layer. Layer 60 is a transparent barrier layer, such as PET, layers 20 are transparent encapsulant layers, layer 30 is a photovoltaic device and layer 40 is a suitable backsheet for the photovoltaic device.

Among the classes of polymers, fluoropolymers are unique materials because they exhibit an outstanding range of properties such as high transparency, good dielectric strength, high purity, chemical inertness, low coefficient of friction, high thermal stability, excellent weathering, and UV resistance. Fluoropolymers are frequently used in applications calling for high performance in which oftentimes the combination of the above properties is required. However fluoropolymers are known to transmit UV light to underlying layers and an improved composition is needed to protect underlying materials.

The phrase “fluoropolymer” is known in the art and is intended to include, for example, polytetrafluoroethylene, copolymers of tetrafluoroethylene and hexafluoropropylene, tetrafluoroethylene-perfluoro(alkyl vinyl ether) copolymers (e.g., tetrafluoroethylene-perfluoro(propyl vinyl ether), FEP (fluorinated ethylene propylene copolymers), polyvinyl fluoride, polyvinylidene fluoride, and copolymers of vinyl fluoride, chlorotrifluoroethylene, and/or vinylidene difluoride (i.e., VDF) with one or more ethylenically unsaturated monomers such as alkenes (e.g., ethylene, propylene, butylene, and 1-octene), chloroalkenes (e.g., vinyl chloride and tetrachloroethylene), chlorofluoroalkenes (e.g., chlorotrifluoroethylene), fluoroalkenes (e.g., trifluoroethylene, tetrafluoroethylene (i.e., TFE), 1-hydropentafluoropropene, 2-hydropentafluoropropene, hexafluoropropylene (i.e. HFP), and vinyl fluoride), perfluoroalkoxyalkyl vinyl ethers (e.g., CF₃OCF₂CF₂CF₂OCF═CF₂); perfluoroalkyl vinyl ethers (e.g., CF₃OCF═CF₂ and CF₃C₂CF₂OCF═CF₂), and combinations thereof.

The fluoropolymer can be melt-processable, for example, as in the case of polyvinylidene fluoride; copolymers of vinylidene fluoride; copolymers of tetrafluoroethylene, hexafluoropropylene, and vinylidene fluoride copolymers of tetrafluoroethylene and hexafluoropropylene; copolymers of ethylene and tetrafluoroethylene and other melt-processable fluoroplastics; or the fluoropolymer may not be melt-processable, for example, as in the case of polytetrafluoroethylene, copolymers of TFE and low levels of fluorinated vinyl ethers, and cured fluoroelastomers.

Useful fluoropolymers include copolymers of HFP, TFE, and VDF (i.e., THV). Examples of THV polymers include those marketed by Dyneon, LLC under the trade designations “DYNEON THV”.

Other useful fluoropolymers also include copolymers of ethylene, TFE, and HFP. Such polymers are marketed, for example, under the trade designation “DYNEON FLUOROTHERMOPLASTIC HTE” by Dyneon, LLC.

Additional commercially available vinylidene fluoride-containing fluoropolymers include, for example, those fluoropolymers having the trade designations; “KYNAR” (e.g., “KYNAR 740”) as marketed by Arkema, Philadelphia, Pa.; “HYLAR” (e.g., “HYLAR 700”) and “SOLEF” as marketed by Solvay Solexis USA, West Deptford, N.J.; and “DYNEON PVDF Fluoroplastics” such as DYNEON FP 109/0001 as marketed by Dyneon, LLC;. Copolymers of vinylidene difluoride and hexafluoropropylene are also useful. These include for example KYNARFLEX (e.g. KYNARFLEX 2800 or KYNARFLEX 2550) as marketed by Arkema.

Commercially available vinyl fluoride fluoropolymers include, for example, those homopolymers of vinyl fluoride marketed under the trade designation “TEDLAR” by E.I. du Pont de Nemours & Company, Wilmington, Del.

Useful fluoropolymers also include copolymers of tetrafluoroethylene and propylene (TFE/P). Such polymers are commercially available, for example, under the trade designations “AFLASas marketed by AGC Chemicals America, or “VITON” as marketed by E.I. du Pont de Nemours & Company, Wilmington, Del.

Useful fluoropolymers also include copolymers of ethylene and TFE (i.e., “ETFE”). Such polymers may be obtained commercially, for example, as marketed under the trade designations “DYNEON FLUOROTHERMOPLASTIC ET 6210A”, “DYNEON FLUOROTHERMOPLASTIC ET 6235”, or by Dyneon, LLC, or under the trade designation “NEOFLON ETFE” from Daikin America Inc (e.g. NEOFLON ETFE EP521, EP541, EP543, EP6100R EP620), or under the trade designation “TEFZEL” from E.I. du Pont de Nemours & Company; Wilmington, Del.

Additionally, useful fluoropolymers include copolymers of ethylene and chlorotrifluoroethylene (ECTFE). Commercial examples include Halar 350 and Halar 500 resin from Solvay Solexis Corp.

Other useful fluoropolymers include substantially homopolymers of chlorotrifluoroethylene (PCTFE) such as Aclar from Honeywell.

Suitable functional groups attached in the modified (functionalized) fluoropolymer are carboxylic acid groups such as maleic or succinic anhydride (hydrolyzed to carboxylic acid groups), carbonates, epoxy, acrylate and its derivative such as methacrylate, phosphoric acid and sulfonic acid. Commercially available modified fluoropolymers include Fluon® LM-ETFE AH from Asahi, Neoflon® EFEP RP5000 and Neoflon® ETFE EP7000 from Daikin and Tefzel®HT2202 from DuPont.

Fluoropolymeric substrates may be provided in any form (e.g., film, tape, sheet, web, beads, particles, or as a molded or shaped article) as long as fluoropolymer can be processed.

Exposure to sunlight and other artificial lights can have adverse effects on the useful life of plastic products. UV radiation can break down the chemical bonds in a polymer. This process is called photo degradation and ultimately causes cracking, chalking, color changes and the loss of physical properties.

To counteract the damaging effect of UV light, UV stabilizers are used to solve the degradation problems associated with exposure to sunlight. UV stabilizers can be categorized by two general classifications—ultraviolet light absorber (UVA) and hindered amine light stabilizers (HALS).

Ultraviolet absorbers function by preferentially absorbing harmful ultraviolet radiation and dissipating it as thermal energy. The commonly available UV absorbers are based on benzophenones (hydroxybenzophenones, e.g., Cyasorb 531 (Cytec)), benzotriazoles (hydroxyphenylbenzotriazoles, e.g., Cyasorb 5411, Tinavin 329 (Ciba Geigy)), triazines (hydroxyphenyltriazines, e.g., Cyasorb 1164), oxanilides, (e.g., Sanuvor VSU (Clariant)) cyanoacrylates (e.g., Uvinol 3039 (BASF)), or benzoxazinones.

Suitable benzophenones include, CYASORB UV-9 (2-hydroxy-4-methoxybenzophenone, CHIMASSORB 81 (or CYASORB UV 531) (2 hyroxy-4 octyloxybenzophenone).

TINUVIN P, TINUVIN 234, TINUVIN 326, TINUVIN 328, CYASORB UV 5411 and CYASORB UV 237 are suitable examples of benzotriazoles.

CYASORB UV 1164 (2-[4,6-bis(2,4-dimethylphenyl)-1,3,5-triazin-2-yl]-5(oxetyloxy) phenol is an exemplary triazine UV absorber.

CYASORB 3638 is a suitable UV absorber which is a benzoxiazine.

Hindered amine light stabilizers (HALS) are extremely efficient stabilizers against light-induced degradation of most polymers. They do not generally absorb UV radiation, but act to inhibit degradation of the polymer. These are typically tetra alkyl piperidines, such as 2,2,6,6-tetramethyl-4-piperidinamine and 2,2,6,6-tetramethyl-4-piperidinol.

Functionalized UV absorbers or HALS can be prepared by methods known in the art, such as by esterification, alkylation, transesterification, and the like. For example, nucleophilic displacement of a halide can occur in the presence of an lithium alkyl reagent (to provide a vinyl or allyl group). Esterification of a hydroxyl group on a UV absorber and acrylic acid methyl ester or methyacrylic methyl ester can provide a acrylate or methacrylate functionalized UV absorber. Similarly, esterification or amidation of a hydroxyl or amine group of a HALS provides a functionalized HALS with an acrylate (acrylamide) or methacrylate (methacrylamide) group.

Suitable functionalized UV absorbers include 2-(2H-benzotriazol-2-yl)-4-methyl-6-(2-propenyl)phenol, CAS Number 2170-39-0, 2-[3-(2H-benzotriazol-2-yl)-4-hydroxyphenyl]ethyl methacrylate, CAS Number 96478-09-0, [4-(allyloxy)-2-hydroxyphenyl](phenyl)methanone, CAS Number 2549-87-3, and 2-(4-benzoyl-3-hydroxyphenoxy)ethyl acrylate, CAS Number 16432-81-8.

Encapsulants are materials that help protect the photovoltaic device. Generally, they are thermoplastic materials. Such materials include, but are not limited to, for example natural or synthetic polymers including polyethylene (including linear low density polyethylene, low density polyethylene, high density polyethylene, etc.), polypropylene, nylons (polyamides), EPDM, polyesters, polycarbonates, ethylene-propylene elastomer copolymers, copolymers of ethylene or propylene with acrylic or methacrylic acids, acrylates, methacrylates, ethylene-propylene copolymers, poly alpha olefin melt adhesives such including, for example, ethyl vinyl acetate (EVA), ethylene butyl acrylate (EBA) ethylene methyl acrylate (EMA); ionomers (acid functionalized polyolefins generally neutralized as a metal salt), acid functionalized polyolefins, polyurethanes including, for example, TPUs, olefin elastomers, olefinic block copolymers, thermoplastic silicones, polyvinyl butyral or mixtures thereof.

Suitable ionomers include, but are not limited to, those known under the tradenames of Surlyn® (DuPont, for example SURLYN PV-4000 or SURLYN 1702) and Iotek® (Exxon Mobil).

Ionomers include, for example, SURLYN PV-4000, or SURLYN 1702 (DuPont). For example, Surlyn® is the random copolymer poly(ethylene-co-methacrylic acid) (EMAA). The incorporation of methacrylic acid is typically low (<15 mol. %). Some or all of the methacrylic acid units can be neutralized with a suitable cation, commonly Na⁺ or Zn⁺². Surlyn® is produced through the copolymerization of ethylene and methacrylic acid via a high pressure free radical reaction, similar to that for the production of low density polyethylene. The neutralization of the methacrylic acid units can be done through the addition an appropriate base in solution, or in the melt mixing of base and copolymer.

Suitable thermoplastic silicones include, but are not limited to those under the tradename Geniomer® (Wacker).

Suitable TPU materials include, but are not limited to those under the tradenames of Elastollan® (BASF), Texin® and Desmopan® (Bayer), Estane® (Lubrizol), Krystalflex®, Krystalgran® Avalon® (Huntsmann).

Polyalpha olefin melt adhesives are known in the art and include, for example, ethylene alpha olefin copolymers such as ethylene vinyl acetate (EVA), ethylene octene, and ethylene propylene.

Suitable polyolefin polymers include but are not limited to ethylene or propylene co-polymers of an C₂₋₂₀ α-olefin, more particularly the α-olefin is selected from the group ethylene, propylene, 1-butene, isobutylene, 1-pentene, 1-heptene, 1-octene, 1-nonene and 1-decene and blends or combinations thereof. Suitable examples include, but are not limited to Tradename examples: Amplify®, Affinity®, Versify®, Engage®, Infuse® (Dow Chemicals), Tafiner® (Mitsui Chemicals), Exact®, Exceed®, Achieve®, Vistamaxx® (Exxon Mobil), Adflex® (Basell), Surpass® (Nova), Notio® (Mitsui).

In particular, suitable PAO hot melt adhesives include ethylene (E)/vinyl acetate (VA) polymers. The ratio of ethylene to vinyl acetate can be controlled and those EVA polymers having a VA content of about 5% to about 40 weight % are particularly useful in this invention. Suitable EVA materials include those available under the tradnmaes Elvax (DuPont, for example PV 1400 and PV 1410) Ateva (AT Plastics), Evatane (Arkema) or Alcudia (Repsol).

Suitable materials for tie layers include ethylene/vinyl acetate (EVA) copolymers, ethylene/methyl acrylate (EMA) and ethylene/butyl acrylate (EBA) copolymers, ethylene/acrylic ester/maleic anhydride or glycidyl methacrylate terpolymers, ethylene/vinyl acetate/maleic anhydride terpolymers, or anhydride grafted polyolefins.

In addition to conventional tie layers, the tie layer can be interchanged with an adhesive layer. Exemplary adhesive materials include thermoset polymers and thermoplastic polymers. In an embodiment, the adhesive layer may be ethyl vinyl acetate (EVA), polyester (PET), polyurethane, a cynoacrylate, epoxy, an olefin, hot melt adhesives, ionomers, silicone adhesives, acrylics, the like, and combinations thereof.

In particular, suitable PAO hot melt adhesives include ethylene (E)/vinyl acetate (VA) polymers. The ratio of ethylene to vinyl acetate can be controlled and those EVA polymers having a VA content of about 5% to about 40 weight % are particularly useful in this invention. Suitable EVA materials include those available under the tradenames Elvax (Dupont, for example PV 1400 and PV 1410), Ateva (AT Plastics), Evatane (Arkema), or Alcudia (Repsol).

The adhesives used to form multilayer films can be waterborne, solvent based, reactive 100% solid (solventless) liquid, or hot melt. Typical large adhesive companies include Loctite, Henkel, 3M, Sartomer, Bostik and many others.

Suitable barrier films include polyester films (e.g., polyethylene terephthalates, polyethylene naphthalates, etc.) coated with inorganic barrier layers, such as, but not limited to SiOx, AlOx, SiNx, SiONx. Such films are available from Toppan (eg. Toppan GL or GX films), Mitsubishi (eg. Techbarrier or Techbarrier LX) and Toray (eg. Barrilox) among others.

Multilayer films of this invention may be formed by a variety of methods including thermal lamination, coextrusion, extrusion coating, and extrusion lamination. Thermal lamination refers the process of contacting two films while applying heat and pressure. Generally this is accomplished by heating at least one of the polymers to or near its softening or melting point. Extrusion coating refers to the process of melting a thermoplastic polymer in a extruder and then passing the molten polymer through a die to control layer thickness and depositing it on a moving substrate. As the polymer cools it solidifies and adheres to the substrate. The rate of cooling may be controlled or accelerated with methods such as chill rolls or air knives The coating may be extruded as a single layer, or as multiple layer by simultaneously extruding multiple layers of polymer through a single die in a process referred to as coextrusion. Extrusion lamination is an alternative embodiment of this process in which a molten polymer is extrusion coated on to a first substrate and then a second substrate is immediately applied to the exposed surface of the molten polymer. The molten polymer adheres the two substrates together as it cools. (See for example, Edward M Petrie, “Adhesion in Extrusion and Coextrusion Processes,” SpecialChem4Adhesives website, Jul. 30, 2008).

The ability to bond surfaces with adhesive or a tie layer can be accomplished by a surface treatment such as corona in air or a solvent (ketone) environment. Additionally, e-beam interlayer crosslinking, UV crosslinking (note with UV blockers this would have to be done through a non blocked side), use of compatible blends or adhesion promoters can be used to effect adhesion amongst the layers.

Generally the first layer, the fluoropolymer, has a thickness of between about 0.1 mil to about 20 mils, between about 1 mil (0.001 inch) and about 10 mils, more particularly between about 2 mils and about 5 mils and in particular between about 0.5 and about 2 mils.

The second layer, the encapsulant, can have any thickness. Generally, the second substrate has a thickness of between about 1 mil and 50 mils, more particularly between about 10 mils and about 30 mils and in particular between about 15 and about 25 mils.

Typically the elevated temperature range for laminating the first and second layers together is at least above the melting point or softening point of the second substrate, and more generally about 20° C. to about 50° C. above the melting point or softening point.

Typically, the lamination of the two heated substrates is conducted under pressure or vacuum. This can be accomplished by many known methods in the art, such as vacuum lamination or roll press lamination. Typical pressure applied to the laminate is about 15 psi to about 45 psi, although it can be higher. When a photovoltaic element is already in contact with the laminate, the pressure is controlled so that the photovoltaic element would not be damaged during processing.

In general, the lamination of the two (or more) substrates is accomplished over a period of from about less than a second and several seconds when a roll press process is utilized. Where vacuum lamination is utilized, the process can take about 5 to about 15 minutes for complete lamination of the two or more materials.

Alternatively, lamination could potentially be done in a roll press. So, for a fluoropolymer film and a non fluoropolymer contacted in a roll press, low pressure might be from about 1 to about 10 psi, medium pressure could be from about 10 to about 100 psi, high pressure could be from about 100 to about 500 psi, and in extreme cases, even up to about 5000 psi for steel-on-steel nips.

The laminates of the invention can be used to protect, in particular, electronic components from moisture, weather, heat, radiation, physical damage and/or insulate the component. Examples of electronic components include, but are not limited to, packaging for crystalline-silicon based thick photovoltaic modules, amorphous silicon, CIGS, or CdTe based thin photovoltaic modules, LEDs, LCDs, printed circuit boards, flexible displays and printed wiring boards.

The following paragraphs enumerated consecutively from 1 through 62 provide for various aspects of the present invention. In one embodiment, in a first paragraph (1), the present invention provides a composition or film comprising:

a fluoropolymer; and

a functionalized ultraviolet (UV) light absorber.

2. The composition or film of paragraph 1, wherein the UV absorber is present in an amount such that the transmittance of the fluoropolymer in the visible range is not substantially decreased.

3. The composition or film of either of paragraphs 1 or 2, wherein the UV absorber is present in an amount of from about 0.1 to about 10 percent by weight, based on total weight of the fluoropolymer.

4. The composition or film of any of paragraphs 1 through 3, wherein the UV absorber is present in an amount of from about 0.5 to about 2 percent by weight, based on the total weight of the fluoropolymer.

5. The composition or film of any of paragraphs 1 through 4, wherein the fluoropolymer is selected from polytetrafluoroethylene, polyvinylidenefluoride, polychlorotrifluoroethlylene, polyvinylfluoride, tetrafluoroethylene/hexafluoropropylene/ethylene copolymer, chlorotrifluoroethylene/vinylidenefluoride copolymer, chlorotrifluoroethylene/hexafluoropropylene, chlorotrifluoroethylene/ethylene copolymers, ethylene/trifluoroethylene copolymers, ethylene/tetrafluoroethylene copolymers, fluorinated ethylene/propylene copolymers or mixtures thereof.

6. The composition or film of any of paragraphs 1 through 5, wherein the functionalized UV absorber is an acrylate, methacrylate, allyl, or vinyl containing UV absorber.

7. The composition or film of paragraph 6, wherein the UV absorber is a benzophenone, a benzotriazole, a triazine, a cyanoacrylate, an oxanilide, or a benzoxazinone.

8. The composition or film of any of paragraphs 1 through 4, 6 or 7, wherein the fluoropolymer is a functionalized fluoropolymer.

9. The composition or film of paragraph 8, wherein the functionalized fluoropolymer includes carboxylic acid, sulfonic acid, phosphonic acid or anhydride functionality in the polymeric backbone.

10. The composition of any of paragraphs 1 through 9, further comprising a functionalized hindered amine light stabilizer (HALS).

11. The composition or film of paragraph 10, wherein the HALS is present in an amount such that the transmittance of the fluoropolymer in the visible range is not substantially decreased.

12. The composition or film of either of paragraphs 10 or 11, wherein the HALS is present in an amount of from about 0.1 to about 5 percent by weight, based on total weight of the fluoropolymer.

13. The composition or film of any of paragraphs 10 through 12, wherein the HALS is present in an amount of from about 0.5 to about 2 percent by weight, based on the total weight of the fluoropolymer.

14. The composition or film of any of paragraphs 10 through 13, wherein the functionalized HALS is an acrylate, methacrylate, allyl, or vinyl containing HALS.

15. The composition or film of paragraph 14, wherein the HALS is a multialkyl substituted piperidineamine or a piperidinol.

16. A composition or film comprising:

a functionalized fluoropolymer; and

a ultraviolet (UV) light absorber.

17. The composition or film of paragraph 16, wherein the UV absorber is present in an amount such that the transmittance of the fluoropolymer in the visible range is not substantially decreased.

18. The composition or film of either of paragraphs 16 or 17, wherein the UV absorber is present in an amount of from about 0.1 to about 10 percent by weight, based on total weight of the fluoropolymer.

19. The composition or film of any of paragraphs 16 through 18, wherein the UV absorber is present in an amount of from about 0.5 to about 2 percent by weight, based on the total weight of the fluoropolymer.

20. The composition or film of any of paragraphs 16 through 19, wherein the UV absorber is a hydroxyl containing UV absorber.

21. The composition or film of paragraph 20, wherein the UV absorber is a benzophenone, a benzotriazole, a triazine, a cyanoacrylate, an oxanilide, or a benzoxazinone.

22. The composition or film of any of paragraphs 16 through 21, wherein the functionalized fluoropolymer includes carboxylic acid, sulfonic acid, phosphonic acid or anhydride functionality in the polymeric backbone.

23. The composition or film of any of paragraphs 16 through 22, further comprising a hindered amine light stabilizer (HALS).

24. The composition or film of paragraph 23, wherein the HALS is present in an amount such that the transmittance of the fluoropolymer in the visible range is not substantially decreased.

25. The composition or film of either of paragraphs 23 or 24, wherein the HALS is present in an amount of from about 0.1 to about 5 percent by weight, based on total weight of the fluoropolymer.

26. The composition or film of any of paragraphs 23 through 25, wherein the HALS is present in an amount of from about 0.5 to about 2 percent by weight, based on the total weight of the fluoropolymer.

27. The composition or film of any of paragraphs 23 through 26, wherein the HALS is a multialkyl substituted piperidineamine or a piperidinol.

28. The composition or film of any of paragraphs 16 through 27, wherein the functionalized fluoropolymer includes carboxylic acid, sulfonic acid, phosphonic acid or anhydride functionality in the polymeric backbone.

29. A polymer comprising a fluoropolymer functionalized with a ultraviolet (UV) light absorber.

30. The polymer of paragraph 29, wherein the UV absorber is present in an amount such that the transmittance of the polymer in the visible range is not substantially decreased.

31. The polymer of either of paragraphs 29 or 30, wherein the UV absorber is present in an amount of from about 0.1 to about 10 percent by weight, based on total weight of the polymer.

32. The polymer of any of paragraphs 29 through 31, wherein the UV absorber is present in an amount of from about 0.5 to about 2 percent by weight, based on the total weight of the polymer.

33. The polymer of any of paragraphs 29 through 32, wherein the fluoropolymer is selected from polytetrafluoroethylene, polyvinylidenefluoride, polychlorotrifluoroethlylene, polyvinylfluoride, tetrafluoroethylene/hexafluoropropylene/ethylene copolymer, chlorotrifluoroethylene/vinylidenefluoride copolymer, chlorotrifluoroethylene/hexafluoropropylene, chlorotrifluoroethylene/ethylene copolymers, ethylene/trifluoroethylene copolymers, ethylene/tetrafluoroethylene copolymers, fluorinated ethylene/propylene copolymers or mixtures thereof.

34. The polymer of any of paragraphs 29 through 33, wherein the UV absorber contained a reactive acrylate, methacrylate, allyl, or vinyl group.

35. The polymer of paragraph 34, wherein the UV absorber is a benzophenone, a benzotriazole, a triazine, a cyanoacrylate, an oxanilide, or a benzoxazinone.

36. The polymer of any of paragraphs 29 through 32, 34 or 35, wherein the fluoropolymer is a functionalized fluoropolymer.

37. The polymer of paragraph 36, wherein the functionalized fluoropolymer includes carboxylic acid, sulfonic acid, phosphonic acid or anhydride functionality in the polymeric backbone.

38. The polymer of any of paragraphs 29 through 37, further functionalized with a hindered amine light stabilizer (HALS).

39. The composition or film of paragraph 38, wherein the HALS is present in an amount such that the transmittance of the polymer in the visible range is not substantially decreased.

40. The polymer of either of paragraphs 38 or 39, wherein the HALS is present in an amount of from about 0.1 to about 5 percent by weight, based on total weight of the polymer.

41. The polymer of any of paragraphs 38 through 40, wherein the HALS is present in an amount of from about 0.5 to about 2 percent by weight, based on the total weight of the polymer.

42. The polymer of any of paragraphs 38 through 41, wherein the HALS contained an acrylate, methacrylate, allyl, or vinyl group.

43. The polymer of paragraph 42, wherein the HALS is a multialkyl substituted piperidineamine or a piperidinol.

44. A polymer comprising a functionalized fluoropolymer and a ultraviolet (UV) light absorber.

45. The polymer of paragraph 44, wherein the UV absorber is present in an amount such that the transmittance of the polymer in the visible range is not substantially decreased.

46. The polymer of either of paragraphs 44 or 45, wherein the UV absorber is present in an amount of from about 0.1 to about 10 percent by weight, based on total weight of the polymer.

47. The polymer of any of paragraphs 44 through 46, wherein the UV absorber is present in an amount of from about 0.5 to about 2 percent by weight, based on the total weight of the polymer.

48. The polymer of any of paragraphs 44 through 47, wherein the UV absorber contained a hydroxyl group.

49. The polymer of paragraph 48, wherein the UV absorber is a benzophenone, a benzotriazole, a triazine, a cyanoacrylate, an oxanilide, or a benzoxazinone.

50. The polymer of any of paragraphs 44 through 49, wherein the functionalized fluoropolymer includes carboxylic acid, sulfonic acid, phosphonic acid or anhydride functionality in the polymeric backbone.

51. The polymer of any of paragraphs 44 through 50, further comprising a hindered amine light stabilizer (HALS).

52. The polymer of paragraph 51, wherein the HALS is present in an amount such that the transmittance of the polymer in the visible range is not substantially decreased.

53. The polymer of either of paragraphs 51 or 52, wherein the HALS is present in an amount of from about 0.1 to about 5 percent by weight, based on total weight of the polymer.

54. The polymer of any of paragraphs 51 through 53, wherein the HALS is present in an amount of from about 0.5 to about 2 percent by weight, based on the total weight of the polymer.

55. The polymer of any of paragraphs 51 through 54, wherein the HALS is a multialkyl substituted piperidineamine or a piperidinol.

56. The polymer of any of paragraphs 44 through 58, wherein the functionalized fluoropolymer includes carboxylic acid, sulfonic acid, phosphonic acid or anhydride functionality in the polymeric backbone.

57. A multilayer film of a first encapsulant layer and any of the compositions, films or polymers of paragraphs 1 through 56.

58. The multilayer film of paragraph 57, further comprising a photovoltaic device in contact with the first encapsulant layer.

59. The multilayer film of paragraph 58, further comprising a second encapsulant layer in contact with the photovolatic device side that is not in contact with the first encapsulant layer.

60. The multilayer film of paragraph 59, further comprising a backsheet in contact with the second encapsulant layer side that is not in contact with the photovoltaic device.

61. The multilayer film of paragraph 60, further comprising a tie layer or adhesive layer and a barrier layer, wherein the tie layer or adhesive layer is located between composition, film or polymer of any of paragraphs 1 through 56 and the barrier layer, wherein the barrier layer is located between the tie layer or adhesive layer and the first encapsulant layer.

62. A method to prepare a modified fluoropolymer that comprises a fluoropolymer with an ultraviolet light absorber polymerized thereto comprising the step: reaction extruding a mixture of an acrylate or methacrylate funtionalized UV absorber, a radical initiator and a reactive fluoropolymer into an article.

The invention will be further described with reference to the following non-limiting Examples. It will be apparent to those skilled in the art that many changes can be made in the embodiments described without departing from the scope of the present invention. Thus the scope of the present invention should not be limited to the embodiments described in this application, but only by embodiments described by the language of the claims and the equivalents of those embodiments. Unless otherwise indicated, all percentages are by weight.

### EXAMPLES

### Comparative Example 1

100 parts by weight of ETFE pellets such as available from Daikin America Inc or DuPont. and 2 parts by weight Tinuvin® P (from Ciba, 2-(2′-Hydroxy-5′-methylphenyl) benzotriazole, CAS 2440-22-4) which belongs to bezontriazoles UV absorber family will be compounded together. Compounding will be conducted on a HAAKE MiniLab extruder by Thermo Scientific Fisher. The HAAKE Minilab will use twin screws to mix and compound the ETFE and the UV absorbers and has a chamber with a capacity of 7 cm³. The temperature will be set at 290° C., and the mixing time will be set for 10 min circulation in the compounding chamber and then the compounded material will be discharged and collected.

### Comparative Example 2

100 parts by weight of Fluon® maleic anhydride functionalized ETFE such as available from DuPont or Asahi, and 2 parts by weight of Tinuvin® P (from Ciba, 2-(2′-Hydroxy-5′-methylphenyl) benzotriazole, CAS 2440-22-4) will be compounded. The compounding will be conducted on a HAAKE MiniLab extruder by Thermo Scientific Fisher. The HAAKE Minilab will use twin screws to mix and compound the ETFE and the UV absorbers and has a chamber with a capacity of 7 cm³. The temperature will be set at 270° C., and the mixing time will be set for 10 min circulation in the compounding chamber and then the compounded materials will be discharged and collected.

### Example 1

Will be compounded like the comparative example 1 except 2-(3-(2H-benzotriazol-2-yl)-4-hydroxylphenyl)ethyl methacrylate will be used. Available from Sigma-Aldrich (assay 99%, melting point 96-98° C., CAS Number 96478-09-0) which is a methacrylate functionalized benzotriazol UV absorber instead of Tinuvin® P, the non-functionalized UV absorbers.

### Example 2

Will be compounded like the comparative example 1 except 2-(2H-benzotriazol-2-yl)-4-methyl-6-(2-propenyl)phenol will be used. Available from Sigma-Aldrich (assay 99%, melting point 98-101° C., CAS Number 2170-39-0) which is a propenyl functionalized benzotriazol UV absorber instead of Tinuvin® P, the non-functionalized UV absorbers.

### Example 3

Will be compounded like the comparative example 1 except 2-(4-benzoyl-3-hydroxyphenoxy)ethyl acrylate will be used. Available from Sigma-Aldrich (assay 98%, melting point 77-80° C., CAS Number 16432-81-8) which is an ethyl acrylate functionalized benzophenone UV absorber.

### Example 4

Will be compounded like the comparative example 2 except Tinuvin® 770 will be used. This is available from Ciba (bis(2,2,6,6-tetramethyl-4-piperidinyl) sebacate, CAS Number 52829-07-9). The reactive compound obtained has 2 parts of Tinuvin 770 light stabilizer grafted onto maleic anhydride functionalized ETFE through the reaction between the secondary amine group from Tinuvin 770 and the anhydride group from anhydride functionalized ETFE.

### Example 5

Will be compounded like the comparative example 2 except 2-(2-hydroxy-5-methyl-benzoyl)-benzoic acid is used. This is available from Sigma-Aldrich (assay 98%, melting point 77-80° C., CAS Number 5493-87-8) which is a carboxylic functionalized benzophenol UV absorbers, along with 2 mass parts of Tinuvin® 770. This is available from Ciba (bis(2,2,6,6-tetramethyl-4-piperidinyl) sebacate, CAS Number 52829-07-9). The reactive compound obtained has 2 parts of benzophenone UV absorber and 2 parts of light stabilizer with respect to 100 mass parts of maleic anhydride functionalized ETFE.

### Example 6

The reactive compound obtained from Example 1 will be compounded with the reactive compound obtained from Example 4 with a 1:1 ratio using the same HAAKE MiniLab extruder at 290° C. for 10 min circulation in the mixing chamber. Then the compound will be discharged from the extruder. The obtained compound will have 1 part of grafted benzotriazol UV absorber and 1 part of grafted light stabilizer Tinuvin® 770 with respect to 100 parts of ETFE.

Although the present invention has been described with reference to preferred embodiments, persons skilled in the art will recognize that changes may be made in form and detail without departing from the spirit and scope of the invention. All references cited throughout the specification, including those in the background, are incorporated herein in their entirety. Those skilled in the art will recognize, or be able to ascertain, using no more than routine experimentation, many equivalents to specific embodiments of the invention described specifically herein. Such equivalents are intended to be encompassed in the scope of the following claims.

What is claimed is:

1. A composition or film comprising:
a fluoropolymer; and
a functionalized ultraviolet (UV) light absorber.

2. The composition or film of claim 1, wherein the UV absorber is present in an amount of from about 0.1 to about 10 percent by weight, based on total weight of the fluoropolymer.

3. The composition or film of claim 1, wherein the fluoropolymer is selected from polytetrafluoroethylene, polyvinylidenefluoride, polychlorotrifluoroethlylene, polyvinylfluoride, tetrafluoroethylene/hexafluoropropylene/ethylene copolymer, chlorotrifluoroethylene/vinylidenefluoride copolymer, chlorotrifluoroethylene/hexafluoropropylene, chlorotrifluoroethylene/ethylene copolymers, ethylene/trifluoroethylene copolymers, ethylene/tetrafluoroethylene copolymers, fluorinated ethylene/propylene copolymers or mixtures thereof.

4. The composition or film of claim 1, wherein the functionalized UV absorber is an acrylate, methacrylate, allyl, or vinyl containing UV absorber.

5. The composition or film of claim 4, wherein the UV absorber is a benzophenone, a benzotriazole, a triazine, a cyanoacrylate, an oxanilide, or a benzoxazinone.

6. The composition or film of claim 1, wherein the fluoropolymer is a functionalized fluoropolymer.

7. The composition or film of claim 6, wherein the functionalized fluoropolymer includes carboxylic acid, sulfonic acid, phosphonic acid or anhydride functionality in the polymeric backbone.

8. The composition of claim 1, further comprising a functionalized hindered amine light stabilizer (HALS).

9. The composition or film of claim 8, wherein the functionalized HALS is an acrylate, methacrylate, allyl, or vinyl containing HALS.

10. A composition or film comprising:
a functionalized fluoropolymer; and
a ultraviolet (UV) light absorber.

11. The composition or film of claim 10, wherein the UV absorber is present in an amount of from about 0.1 to about 10 percent by weight, based on total weight of the fluoropolymer.

12. The composition or film of claim 10, wherein the UV absorber is a hydroxyl containing UV absorber.

13. The composition or film of claim 12, wherein the UV absorber is a benzophenone, a benzotriazole, a triazine, a cyanoacrylate, an oxanilide, or a benzoxazinone.

14. The composition or film of claim 10, wherein the functionalized fluoropolymer includes carboxylic acid, sulfonic acid, phosphonic acid or anhydride functionality in the polymeric backbone.

15. The composition or film of claim 10, further comprising a hindered amine light stabilizer (HALS).

16. The composition or film of claim 10, wherein the functionalized fluoropolymer includes carboxylic acid, sulfonic acid, phosphonic acid or anhydride functionality in the polymeric backbone.

17. A method to prepare a modified fluoropolymer that comprises a fluoropolymer with an ultraviolet light absorber polymerized thereto comprising the step:
reacting a mixture of an acrylate, methacrylate, allyl or vinyl funtionalized UV absorber and a reactive fluoropolymer.

18. The method of claim 17, wherein the reactive fluoropolymer includes carboxylic acid, sulfonic acid, phosphonic acid or anhydride functionality in the polymeric backbone and the functionalized UV absorber is benzophenone, a benzotriazole, a triazine, a cyanoacrylate, an oxanilide, or a benzoxazinone with a reactive acrylate moiety.

19. The composition or film of claim 1, further comprising a photovoltaic device adjacent to the composition or film.

20. The composition or film of claim 10, further comprising a photovoltaic device adjacent to the composition or film.
